(19) United States
(12) Patent Application Publication
(10) Pub. No.: US 2026/0014652 A1
(43) Pub. Date: Jan. 15, 2026

(54) Electronic Device and Method For Manufacturing Electronic Device

(71) Applicant: Hitachi Astemo, Ltd., Hitachinaka-shi, Ibaraki (JP)

(72) Inventors: Osamu IKEDA, Tokyo (JP); Yujiro KANEKO, Hitachinaka-shi, Ibaraki (JP); Yusuke TAKAGI, Hitachinaka-shi, Ibaraki (JP)

(21) Appl. No.: 18/996,115

(22) PCT Filed: Jun. 7, 2023
(86) PCT No.: PCT/JP2023/021219

§ 371 Date: Jan. 17, 2025

(30) Foreign Application Priority Data
Aug. 16, 2022 (JP) 2022-129483

(51) Int. Cl. B23K 35/26; B23K 101/40; C22C 13/00; H01L 23/00

(52) U.S. Cl. CPC B23K 35/262; C22C 13/00; H01L 24/29; B23K 2101/40; H01L 2224/29111; H01L 2924/014

(57) ABSTRACT

An electronic device includes: a first electronic component which has a Ni-based electrode; and a second electronic component which is joined to the Ni-based electrode via Sn-based solder. A (Cu, Ni, Pd)₆Sn₅ compound layer exists at a joint interface between the Ni-based electrode and the Sn-based solder, and content of Pd existing as a (Pd, Ni)Sn₄ compound in a parent phase of the Sn-based solder after joining is less than content of Pd existing as the (Cu, Ni, Pd)₆Sn₅ compound layer or is zero.

### TECHNICAL FIELD

The present invention relates to an electronic device and a method for manufacturing the electronic device.

### BACKGROUND ART

Since the use of lead included in electronic control devices mounted on automobiles is regulated by the RoHS command and the ELV command, lead-free solder mainly composed of Sn-3Ag-0.5Cu (wt %) has been promoted so far. A power module used in an inverter is required to have high power density for the purpose of miniaturization and weight reduction, and for example, the following two points are required. First, the upper and lower surfaces of a power semiconductor are to be soldered to allow heat dissipation from the upper and lower surfaces of the power module. Second, the guaranteed temperature of a power semiconductor joint is to be increased to allow a large amount of current to flow.

A Ni-based electrode for joining with solder is used as an electrode of a semiconductor element, and the resurfaced layer of the electrode is metallized with Au or Ag in order to easily secure solder wetting. However, depending on a heating or storage environment in a chip manufacturing process, Ni may be diffused on the surface of thin Au metallization or Ag metallization with many defects to generate Ni oxide on the outermost surface from the resurfaced layer, which impairs the joinability of the solder. Therefore, in order not to form Ni oxide on the resurfaced layer, a Pd layer is provided on the Ni-based electrode, and Au or Ag metallization is applied on the Pd layer. PTL 1 discloses an alloy for lead-free solder balls consisting of Ag: 3 to 6%, Cu: 1 to 4%, Co: 0.01 to 2%, and Sn: the remainder, in atom %.

### CITATION LIST

### Patent Literature

PTL 1: Japanese Patent No. 3724486

### SUMMARY OF INVENTION

### Technical Problem

In the invention described in PTL 1, there is room for study on countermeasures against shrinkage cavities.

### Solution to Problem

An electronic device according to a first aspect of the present invention includes: a first electronic component which has a Ni-based electrode; and a second electronic component which is joined to the Ni-based electrode via Sn-based solder. A (Cu, Ni, Pd)6Sn5 compound layer exists at a joint interface between the Ni-based electrode and the Sn-based solder, and content of Pd existing as a (Pd, Ni)Sn4 compound in a parent phase of the Sn-based solder after joining is less than content of Pd existing as the (Cu, Ni, Pd)6Sn5 compound layer or is zero.

A method for manufacturing an electronic device according to a second aspect of the present invention is a method for manufacturing an electronic device including a first electronic component having a Ni-based electrode and a second electronic component joined to the Ni-based electrode via Sn-based solder. The method includes: a disposing step of, in the first electronic component in which a Pd layer is formed on an outer periphery of the Ni-based electrode, disposing Sn-based solder containing Cu more than eutectic composition on a surface of the Pd layer. In the electronic device, a (Cu, Ni, Pd)6Sn5 compound layer is formed at a joint interface between the Ni-based electrode and the Sn-based solder.

### Advantageous Effects of Invention

According to the present invention, it is possible to suppress the formation of shrinkage cavities.

### BRIEF DESCRIPTION OF DRAWINGS

FIG. 1 is a diagram illustrating an example of shrinkage cavities.

FIG. 2 is a diagram illustrating behavior of solder during cooling.

FIG. 3 is a diagram illustrating a first configuration of an electronic component.

FIG. 4 is a diagram illustrating a configuration using a general solder.

FIG. 5 is a diagram illustrating a second configuration of the electronic component.

FIG. 6 is a diagram illustrating a method for manufacturing a semiconductor device.

FIG. 7 is a diagram illustrating Examples 1 to 6.

FIG. 8 is a diagram illustrating Comparative Examples 1 and 2.

FIG. 9 is a diagram illustrating a method for manufacturing the semiconductor device.

FIG. 10 is a diagram illustrating Examples 7 to 9.

FIG. 11 is a diagram illustrating Comparative Examples 3 and 4.

### DESCRIPTION OF EMBODIMENTS

### First Embodiment

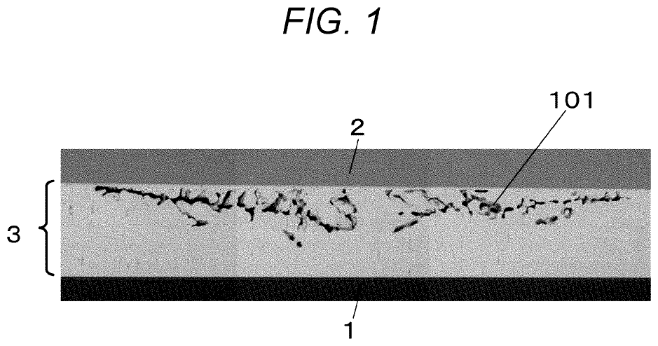

Hereinafter, a semiconductor device as an electronic component according to a first embodiment will be described with reference to FIGS. 1 to 11. In the case of using a chip in which a palladium (Pd) layer is provided on a nickel (Ni)-based electrode, there is a known problem that shrinkage cavities are easily generated in a solder joint as compared with the case of using a chip having no Pd layer.

FIG. 1 is a diagram illustrating an example of shrinkage cavities. In FIG. 1, a solder joint 3 is formed between a semiconductor element 1 and an emitter-side lead 2 of a power module. Shrinkage cavities 101 displayed in black is formed in a region of the solder joint 3 close to the emitter-side lead 2. Note that in the example illustrated in FIG. 1, more heat was dissipated from the semiconductor element 1 side than from the emitter-side lead 2 side. When the shrinkage cavities are formed, a heat dissipation path for releasing heat of the semiconductor element generated by energization is reduced, and it becomes difficult to secure reliability. Therefore, when shrinkage cavities are formed, it is determined as a defective product in quality inspection after assembly. It is considered that the shrinkage cavities are generated since a liquidus temperature of Sn (tin)-based lead-free solder increases as Pd formed on the Ni-based electrode of the semiconductor element diffuses into the melted Sn (tin)-based lead-free solder at the time of solder joining.

Examples of the Ni-based electrode in the present embodiment include only nickel, nickel and phosphorus, nickel and vanadium, and the like. In this case, a ratio of nickel to phosphorus is, for example, about 100:1 to 15. In this case, a ratio of nickel to vanadium is, for example, about 100:1 to 15.

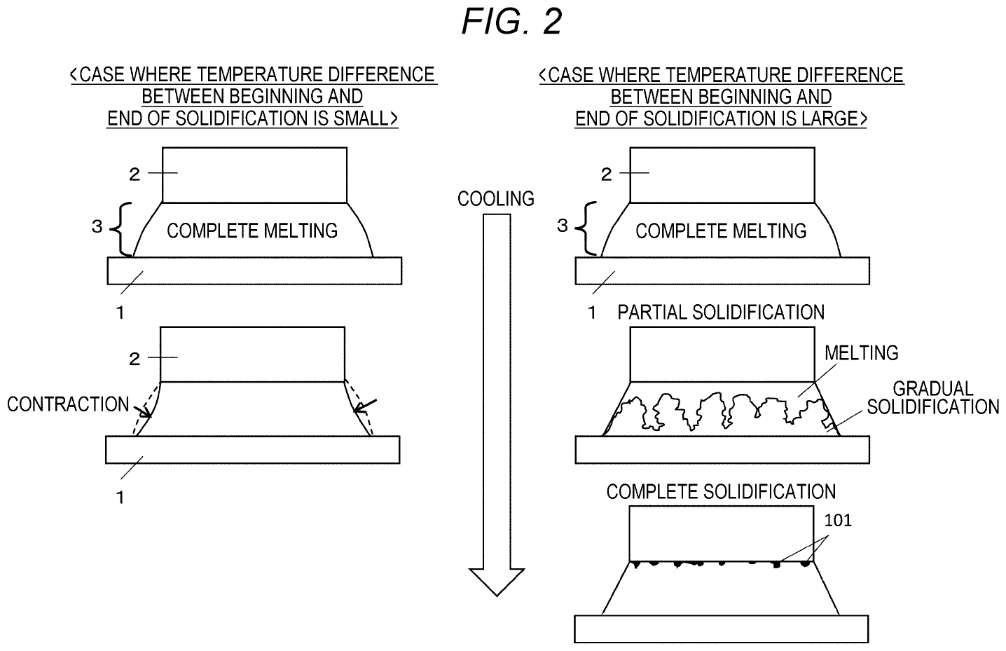

FIG. 2 is a diagram illustrating behavior of the solder during cooling. The left side of FIG. 2 illustrates a case where a temperature difference between the beginning and the end of solidification of the solder is small, and the right side of FIG. 2 illustrates a case where the temperature difference between the beginning and the end of solidification of the solder is large. In FIG. 2, time progresses from an upper side to a lower side in the drawing. In addition, in the example illustrated in FIG. 2, a large amount of heat is dissipated from the semiconductor element 1 side. In a case where the temperature difference between the beginning and the end of solidification of the solder is small as illustrated on the left side of FIG. 2, the entire solder joint 3 undergoes overall contraction under the influence of volumetric contraction due to solidification. On the other hand, in a case where the temperature difference between the beginning and the end of solidification of the solder is large as illustrated on the right side of FIG. 2, the solder is solidified little by little from the cooled side, and the final solidification portion is subjected to volumetric contraction during solidification, so that the shrinkage cavities 101 are easily formed. Note that in a case where more heat is dissipated from the emitter-side lead 2 side than from the semiconductor element 1 side, the shrinkage cavities 101 are formed on the semiconductor element 1 side.

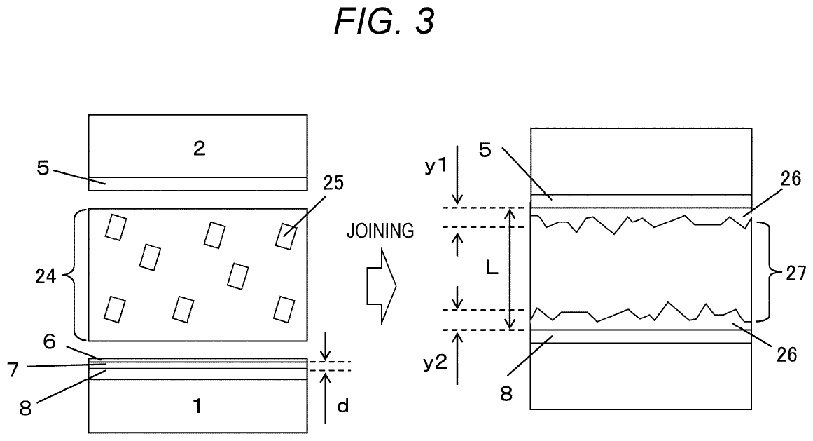

FIG. 3 is a diagram illustrating a first configuration of a semiconductor device 100 that is an electronic component according to the present embodiment. The left side in the drawing illustrates a state before joining, and the right side in the drawing illustrates a state after joining. A Ni-based electrode 8, a Pd layer 7, and a metal film 6 exist on the surface of the semiconductor element 1. The metal film 6 is metallized with Au (gold) or Ag (silver). Ni plating 5 exists on the surface of the emitter-side lead 2. In the present embodiment, a copper-added solder 24 is disposed and joined between the metal film 6 and the Ni plating 5. The copper-added solder 24 is Sn-based solder to which Cu (copper) is added more than eutectic composition. Specifically, in the copper-added solder 24, the weight % of Cu is 0.9% or more, preferably 3% or more and less than 6%, and the weight % of Sn is 80% or more.

The copper-added solder 24 containing more Cu than the eutectic composition contains a large amount of a Cu₆Sn₅ compound indicated by reference numeral 25 in the solder. By joining using the Cu₆Sn₅ compound, Pd is incorporated into the Cu₆Sn₅ compound supplied from the solder, and a compound can be formed at a joint interface 26 as a (Cu, Ni, Pd)₆Sn₅ compound. The solder joint includes the joint interface 26 existing above and below in the drawing and a solder central layer 27.

At this time, the content of Cu contained in the solder and a thickness L of the solder joint is controlled according to the Pd thickness of the semiconductor element 1, so that Pd can be substantially incorporated into the (Cu, Ni, Pd)₆Sn₅ compound formed at the joint interface 26. Here, the thickness of the Pd layer 7 is represented by a symbol d, the thickness of the Pd layer is represented by the symbol d, the thickness of the upper joint interface 26 is represented by a symbol y1, the thickness of the lower joint interface 26 is represented by a symbol y2, the density of Pd is represented by a symbol D1, and the density D2 of (Cu, Ni, Pd)₆Sn₅ is represented by a symbol D2. Since Pd in (Cu, Ni, Pd)₆Sn₅ is 3.6 wt %, following Expression 1 is established with respect to the weight of Pd. The left side of Expression 1 describes Pd before joining, and the right side describes Pd after joining. Note that “x” in Expression 1 is an operation symbol meaning a product.

$$d \times D 1 = ( y 1 + y 2 ) \times D 2 \times 0.036 \qquad ( Expression 1 )$$

Here, the Pd density D1 is 12.03 g/cm3 and the (Cu, Ni, Pd)₆Sn₅ density D2 is 8.33 g/cm3, and thus following Expression 2 is obtained by rearranging Expression 1.

$$y = y 1 + y 2 = 40.1 \times d \qquad ( Expression 2 )$$

That is, Expression 2 shows that the sum of the thickness of the upper joint interface 26 and the thickness of the lower joint interface 26 is about 40 times the thickness of the Pd layer 7 before joining. Note that in a case where the desired solder thickness L is determined, the required Cu content of the solder can be calculated on the basis of the thickness y of the joint interface 26.

If all of Pd can be taken into the joint interface 26, the (Pd, Ni)Sn4 compound hardly exists in the solder central layer 27, and an increase in liquidus temperature can be suppressed, so that shrinkage cavities can be suppressed. The effect of suppressing shrinkage cavities are remarkably obtained when the content of Pd existing as the (Pd, Ni) Sn₄ compound in the parent phase of the Sn-based solder after joining is less than the content of Pd existing as the (Cu, Ni, Pd)₆Sn₅ compound layer described above or is zero. Note that the Ni content in the (Cu, Ni, Pd)₆Sn₅ compound layer is 5 wt % or less.

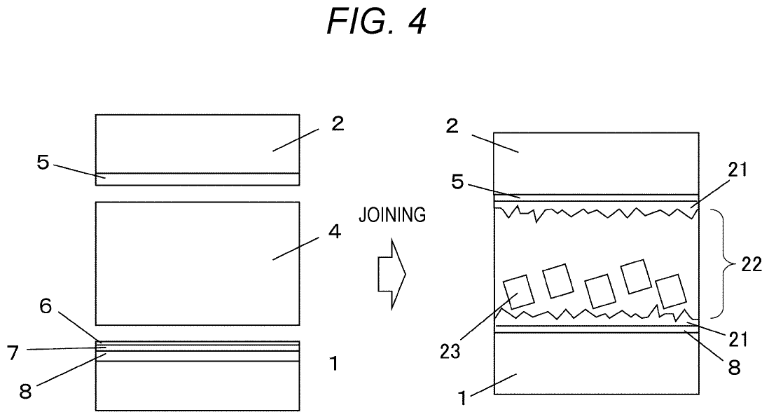

FIG. 4 is a diagram illustrating a configuration using a general solder for comparison. The left side in the drawing illustrates a state before joining, and the right side in the drawing illustrates a state after joining. When the left side of FIG. 4 is compared with the left side of FIG. 3, the general solder 4 is used instead of the copper-added solder 24 in FIG. 3. The Ni-based electrode 8, the Pd layer 7, and the metal film 6 exists on the surface of the semiconductor element 1, and the Ni plating 5 exists on the surface of the emitter-side lead 2, which are common with FIG. 3. The general solder 4 is, for example, Sn-based lead-free solder such as Sn-3Ag-0.5Cu.

In this case, Pd contained in the Pd layer 7 is distributed to those incorporated as a component of the (Ni, Cu, Pd)₃Sn₄ compound formed at the joint interface by reacting with the solder and those existing in a floating island shape as the (Pd, Ni)Sn₄ compound inside the solder joint. Here, when the joint is considered as being divided into an intermetallic compound at the joint interface and the other solder portion, the intermetallic compound formed at the joint interface does not relate to the liquidus temperature of the solder, but the liquidus temperature of the other solder portion affects the likelihood of formation of shrinkage cavities. Here, the more the (Pd, Ni)Sn₄ compound 23 is formed, the higher the liquidus temperature of the solder and the more likely the shrinkage cavities are formed.

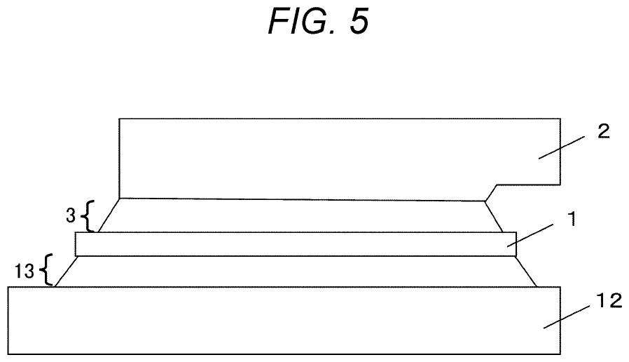

FIG. 5 is a diagram illustrating a second configuration of the semiconductor device 100 according to the present embodiment. In the semiconductor element 1 such as a power module, both surfaces on an emitter side and a collector side may be soldered as illustrated in FIG. 5. Specifically, the semiconductor element 1 illustrated in FIG. 5 is sandwiched between a collector-side lead 12 on the lower side in the drawing and an emitter-side lead 2 on the upper side in the drawing. In this case, since the semiconductor element 1 is cooled from the collector-side lead 12 on the lower side in the drawing, a collector-side joint denoted by reference numeral 13 existing on the lower side of the semiconductor element 1 is cooled faster, and an emitter-side joint denoted by reference numeral 3 is cooled slower. Since shrinkage cavities are more likely to occur as a cooling rate is slower, the shrinkage cavities are more likely to be formed on the side of the emitter-side joint. Therefore, at least at the emitter-side joint, formation of shrinkage cavities can be suppressed by joining the semiconductor element having Pd on the Ni-based electrode with the Sn-based solder to which Cu is added in an amount larger than the eutectic composition.

### Examples 1 to 6

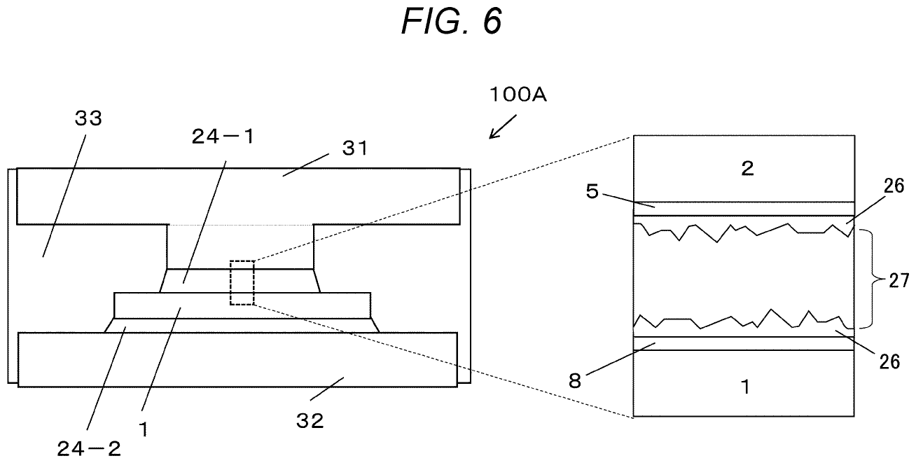

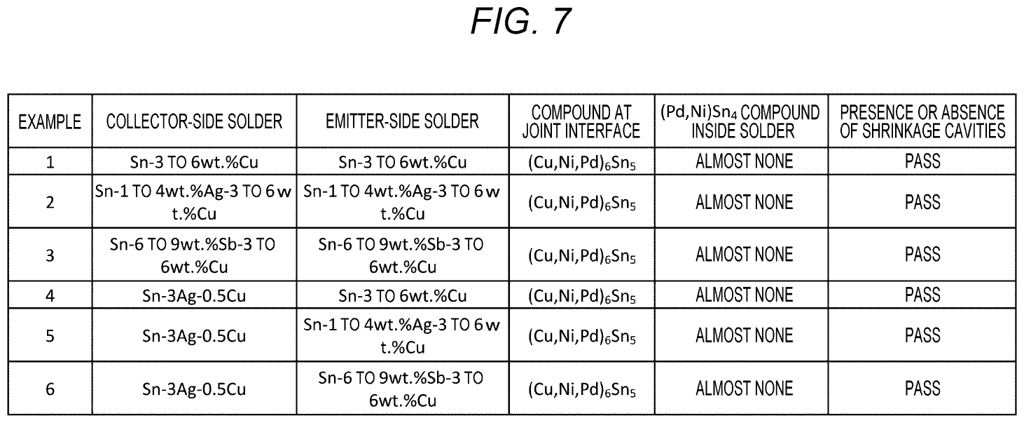

Examples 1 to 6 will be described with reference to FIGS. 6 and 7. A method for manufacturing a semiconductor device 100A illustrated in FIG. 6 is as follows. First, collector-side solder 24-2 is supplied to a solder mounting position of a Cu collector-side lead 32 having roughened Ni plating. The semiconductor element 1 having a Pd layer with a thickness of 600 nm on the Ni-based electrodes on both surfaces is joined thereon. Further, emitter-side solder 24-1 is disposed on the electrode on the upper surface of the joined semiconductor element 1, and a copper emitter-side lead 31 having roughened Ni plating is laminated thereon and joined. Accordingly, Pd supplied from the semiconductor element can be taken into the (Cu, Ni, Pd)₆Sn₅ compound at the joint interface in a state where there is almost no (Pd, Ni) Sn₄ compound inside the joint at the emitter-side joint where shrinkage cavities are likely to be formed. Thereafter, sealing is performed with resin 33 by transfer molding, and the semiconductor device 100A is manufactured.

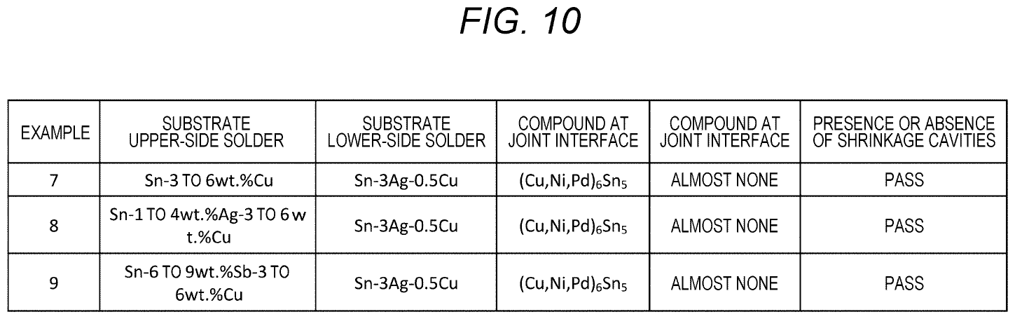

The compositions of the emitter-side solder 24-1 and the collector-side solder 24-2 for each of Examples are as described in the columns of “substrate upper-side solder” and “substrate lower-side solder” in FIG. 10, respectively. For example, in Example 1, both the collector-side solder 24-2 and the emitter-side solder 24-1 are solders containing Sn as a main component and containing 3 wt % or more and less than 6 wt % of Cu. In Example 2, both the collector-side solder 24-2 and the emitter-side solder 24-1 are solders containing Sn as a main component and containing 4 wt % of Ag and 3 wt % or more and less than 6 wt % of Cu.

For each of Examples, 100 semiconductor devices 100A were manufactured, and the presence of the shrinkage cavities 101 was evaluated. The evaluation of the shrinkage cavities 101 was “pass” in a case where no shrinkage cavities 101 exceeding 5% of a joint area were observed in any of the 100 semiconductor devices, and “fail” in a case where the shrinkage cavities 101 exceeding 5% were observed even in one semiconductor device. As a result, all of Examples 1 to 6 were determined as “pass”.

### Comparative Examples 1 and 2

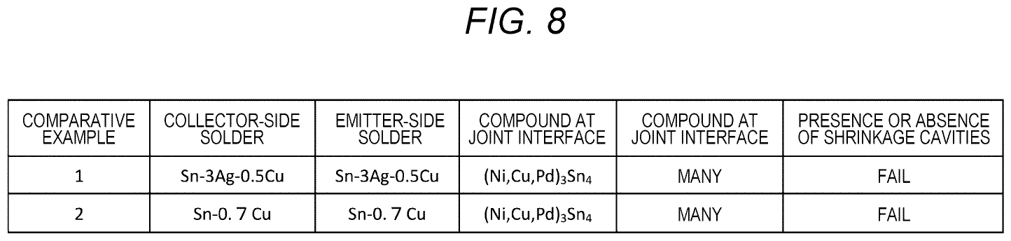

Comparative Example 1 and 2 will be described with reference to FIGS. 6 and 8. In Comparative Examples 1 and 2 different from Examples 1 to 6 only in the composition of the emitter-side solder 24-1 and the collector-side solder 24-2, the semiconductor device was prepared and evaluated in the same manner. As a result of evaluation, all of Comparative Examples 1 and 2 were determined as “fail”.

### Examples 7 to 9

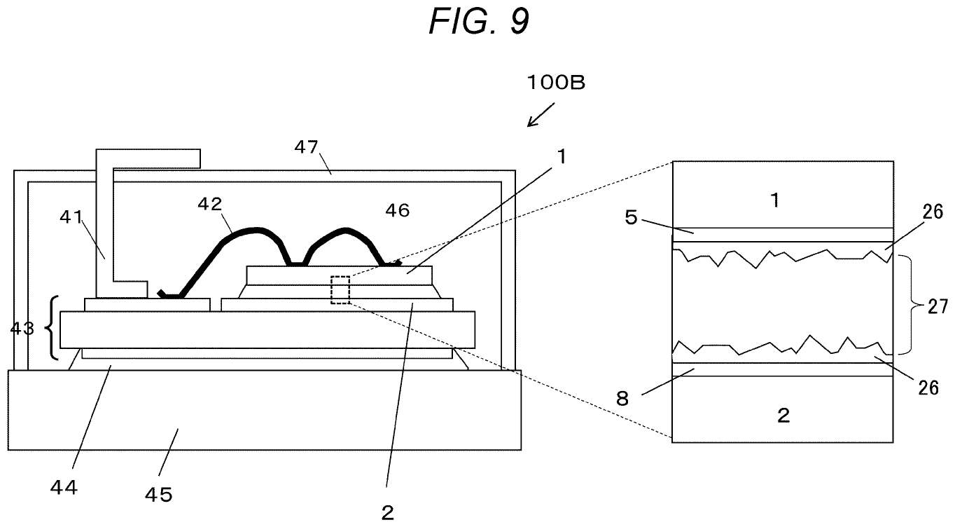

Examples 7 to 9 will be described with reference to FIGS. 9 and 10. A method for manufacturing a semiconductor device 100B illustrated in FIG. 9 is as follows. First, a sheet of substrate lower-side solder 24-4 is placed on a heat dissipation base 45, and a ceramic insulating substrate 43 is laminated thereon. The emitter-side lead 2 is disposed on the upper side of the ceramic insulating substrate 43 in the drawing. Next, substrate upper-side solder 24-3 is placed on the emitter-side lead 2, the semiconductor element 1 is installed, and then heating is performed for joining. Further, after the solder is joined, an aluminum wire 42 and a terminal 41 are joined, and then a case 47 is attached. Finally, the inside of the case 47 is sealed with gel 46 to manufacture the semiconductor device 100B.

The compositions of the substrate upper-side solder 24-3 and the substrate lower-side solder 24-4 for each of Examples are as described in the columns of “substrate upper-side solder” and “substrate lower-side solder” in FIG. 10, respectively. For each of Examples, 100 semiconductor devices 100B were manufactured, and the presence of the shrinkage cavities 101 was evaluated. The evaluation of the shrinkage cavities 101 was “pass” in a case where no shrinkage cavities 101 exceeding 5% of a joint area were observed in any of the 100 semiconductor devices, and “fail” in a case where the shrinkage cavities 101 exceeding 5% were observed even in one semiconductor device. As a result, as illustrated in FIG. 10, all of Examples 7 to 9 were determined as “pass”.

### Comparative Examples 3 and 4

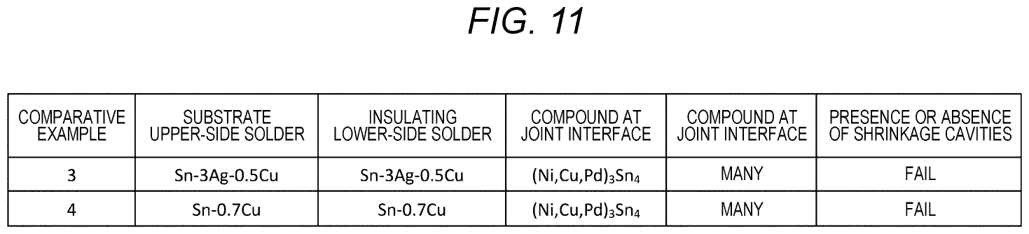

Comparative Example 3 and 4 will be described with reference to FIGS. 9 and 11. Those examples are different from Examples 7 to 9 only in the compositions of the substrate upper-side solder 24-3 and the substrate lower-side solder 24-4. In Comparative Examples 3 and 4, a semiconductor device was prepared and evaluated in the same manner. The compositions of the substrate upper-side solder 24-3 and the substrate lower-side solder 24-4 of Comparative Examples 3 and 4 are as described in the columns of “substrate upper-side solder” and “substrate lower-side solder” in FIG. 11, respectively. As a result of evaluation, all of Comparative Examples 1 and 2 were determined as “fail”.

According to the first embodiment described above, the following operational effects can be obtained.
(1) The semiconductor device 100 as an electronic device includes the semiconductor element 1 which has a Ni-based electrode and the emitter-side lead 2 which is joined to the Ni-based electrode via Sn-based solder. A (Cu, Ni, Pd)₆Sn₅ compound layer exists at the joint interface 26 between the Ni-based electrode and the Sn-based solder, and content of Pd existing as a (Pd, Ni) Sn₄ compound in a parent phase of the Sn-based solder after joining is less than content of Pd existing as the (Cu, Ni, Pd)₆Sn₅ compound layer or is zero. Therefore, the formation of the shrinkage cavities 101 is suppressed.
(2) The semiconductor element 1 includes a plurality of Ni-based electrodes, and the (Cu, Ni, Pd)₆Sn₅ compound layer exists at least at a joint interface between the Ni-based electrode, which requires the longest time for heat dissipation among the plurality of Ni-based electrodes, and the Sn-based solder. For example, in the example illustrated in FIG. 6, since heat is dissipated from the collector-side lead 32 side at the lower side in the drawing, the shrinkage cavities 101 are less likely to be formed in the collector-side solder 24-2 that is cooled early, and thus, the necessity of the countermeasure is low. However, on the side requiring time for cooling, that is, on the emitter side in the example of FIG. 6, there is a possibility that shrinkage cavities 101 may be formed in a case where no countermeasure is taken. Therefore, the formation of the shrinkage cavities 101 is suppressed by using the solder having the composition described above.
(3) In the semiconductor device 100, the (Cu, Ni, Pd)₆Sn₅ compound layer has Ni content of 5 wt % or less.
(4) A method for manufacturing the semiconductor device 100 including the semiconductor element 1 having a Ni-based electrode and the emitter-side lead 2 joined to the Ni-based electrode via Sn-based solder includes a disposing step of, in the semiconductor element 1 in which a Pd layer is formed on an outer periphery of the Ni-based electrode, disposing the copper-added solder 24 containing Cu more than eutectic composition on a surface of the Pd layer. In the semiconductor device 100, a (Cu, Ni, Pd)₆Sn₅ compound layer is formed at a joint interface between the Ni-based electrode and the Sn-based solder.
(5) The semiconductor element 1 has a plurality of Ni-based electrodes. In the disposing step, the copper-added solder 24 containing Cu more than the eutectic composition is disposed at least between the Ni-based electrode on the upper side in FIG. 6, which requires time for heat dissipation, and the emitter-side lead 31.
(6) The composition of the copper-added solder 24 containing more Cu than the eutectic composition contains 3 to 6 wt % of Cu.
(7) As described with reference to FIG. 3, a (Cu, Ni, Pd)₆Sn₅ compound layer having the thickness L that is 40 times a thickness d of the Pd layer on the Ni electrode of the semiconductor element 1 is formed at the joint interface.

### First Modification

In the first embodiment described above, the composition of the solder for suppressing the formation of the shrinkage cavities 101 in the joint of the power module that is the semiconductor element has been described. However, since the formation of the shrinkage cavities 101 can be a problem in every situation of the electronic component, the application target of the present invention is not limited to the power module, and can be various semiconductor elements. Furthermore, the present invention is not limited to a semiconductor, and can be applied to various electronic devices including electrodes.

The embodiment and modification described above may be combined with each other. Although various embodiments and modifications have been described above, the present invention is not limited to these contents. Other embodiments considered within the scope of the technical idea of the present invention are also included within the scope of the present invention.

### REFERENCE SIGNS LIST

1 semiconductor element
7 Pd layer
8 Ni-based electrode
12 collector-side lead
24 copper-added solder
24-1 emitter-side solder
24-2 collector-side solder
24-3 substrate upper-side solder
24-4 substrate lower-side solder
31 emitter-side lead
32 collector-side lead
100, 100A, 100B semiconductor device
101 shrinkage cavities

1. An electronic device comprising:
a first electronic component which has a Ni-based electrode; and
a second electronic component which is joined to the Ni-based electrode via Sn-based solder,
wherein a (Cu, Ni, Pd)₆Sn₅ compound layer exists at a joint interface between the Ni-based electrode and the Sn-based solder, and
content of Pd existing as a (Pd, Ni) Sn₄ compound in a parent phase of the Sn-based solder after joining is less than content of Pd existing as the (Cu, Ni, Pd)₆Sn₅ compound layer or is zero.

2. The electronic device according to claim 1, wherein the first electronic component is a semiconductor element.

3. The electronic device according to claim 1, wherein
the first electronic component is a semiconductor element including a plurality of the Ni-based electrodes, and
the (Cu, Ni, Pd)₆Sn₅ compound layer exists at least at a joint interface between the Ni-based electrode, which requires a longest time for heat dissipation among the plurality of Ni-based electrodes, and the Sn-based solder.

4. The electronic device according to claim 1, wherein the (Cu, Ni, Pd)₆Sn₅ compound layer has Ni content of 5 wt % or less.

5. A method for manufacturing an electronic device including a first electronic component having a Ni-based electrode and a second electronic component joined to the Ni-based electrode via Sn-based solder, the method comprising:
a disposing step of, in the first electronic component in which a Pd layer is formed on an outer periphery of the Ni-based electrode, disposing Sn-based solder containing Cu more than eutectic composition on a surface of the Pd layer,
wherein in the electronic device, a (Cu, Ni, Pd)₆Sn₅ compound layer is formed at a joint interface between the Ni-based electrode and the Sn-based solder.

6. The method for manufacturing an electronic device according to claim 5, wherein the first electronic component is a semiconductor element.

7. The method for manufacturing an electronic device according to claim 5, wherein
the first electronic component is a semiconductor element including a plurality of the Ni-based electrodes, and
in the disposing step, the Sn-based solder containing Cu more than the eutectic composition is disposed at least between the Ni-based electrode, which requires a longest time for heat dissipation among the plurality of Ni-based electrodes, and the second electronic component.

8. The method for manufacturing an electronic device according to claim 5, wherein the composition of the Sn-based solder containing Cu more than the eutectic composition contains 3 to 6 wt % of Cu.

9. The method for manufacturing an electronic device according to claim 5, wherein a (Cu, Ni, Pd)₆Sn₅ compound layer having a thickness being 40 times a thickness of the Pd layer on the Ni electrode of the first electronic component is formed at the joint interface.
